(19) United States
(12) Patent Application Publication
(10) Pub. No.: US 2026/0215161 A1
(43) Pub. Date: Jul. 23, 2026

(54) HOUSING ASSEMBLY FOR A PIEZO-ELECTRIC MATERIAL

(71) Applicant: BETTER HEARING S.A.A.K. TECHNOLOGIES LTD., Givatl Elah (IL)

(72) Inventor: Shay KAPLAN, Givat Elah (IL)

(73) Assignee: BETTER HEARING S.A.A.K. TECHNOLOGIES LTD., Givatl Elah (IL)

(21) Appl. No.: 19/547,410

(22) Filed: Feb. 23, 2026

Related U.S. Application Data
(63) Continuation of application No. PCT/IB2023/060930, filed on Oct. 30, 2023.
(60) Provisional application No. 63/533,716, filed on Aug. 21, 2023.

(51) Int. Cl. H10N 30/88

(52) U.S. Cl. CPC H10N 30/88

(57) ABSTRACT

A housing assembly for a piezo-electric element, comprising: a piezo holder adapted to accept a piezo-electric element; and a piezo cover having a plurality of lateral openings adapted to allow signal wires to pass through and connect to the piezo-electric element, wherein the piezo holder is adapted to enable relative movement of the piezo holder and the piezo cover when the piezo-electric element expands and contracts.

### CROSS REFERENCE TO RELATED APPLICATIONS

This application is a continuation of PCT Application No. PCT/IB2023/060930, filed on Oct. 30, 2023, which claims the benefit of and priority to U.S. Provisional Application No. 63/533,716 filed on Aug. 21, 2023, the contents of which are hereby incorporated by reference in its entirety herein.

### TECHNICAL FIELD

The disclosure generally relates to piezo-electric devices and more specifically to piezo housing assembly for containing a piezo-electric element for use as an actuator.

### BACKGROUND

Some devices that utilize piezo-electric devices, such as piezo-electric stack, are used in harsh environments, such as, for example, in the human body. The human body is a harsh environment because the body attacks any foreign object that is implanted in it. Thus, a piezo-electric based actuator for implantation in a human body may be coated with protective coatings such as Parylene C, layers of compounds like Alumina deposited by ALD or similar process. The coating or enclosure must be engineered to permit movement in the direction of actuation, i.e., the direction in which the piezo-electric device gets longer/shorter. In other words, the coating or the container must be able to expand and contract along with the piezo-electric device, which is not easy to achieve.

Therefore, there is a need to provide a housing assembly for a piezo-electric material that can overcome the above-mentioned problem.

### SUMMARY

A summary of several example embodiments of the disclosure follows. This summary is provided for the convenience of the reader to provide a basic understanding of such embodiments and does not wholly define the breadth of the disclosure. This summary is not an extensive overview of all contemplated embodiments and is intended to neither identify key or critical elements of all embodiments nor to delineate the scope of any or all aspects. Its sole purpose is to present some concepts of one or more embodiments in a simplified form as a prelude to the more detailed description that is presented later. For convenience, the term “certain embodiments” may be used herein to refer to a single embodiment or multiple embodiments of the disclosure.

Certain embodiments disclosed herein include a housing assembly for a piezo-electric element, comprising: a piezo holder adapted to accept a piezo-electric element; and a piezo cover having a plurality of lateral openings adapted to allow signal wires to pass through and connect to the piezo-electric element, wherein the piezo holder is adapted to enable relative movement of the piezo holder and the piezo cover when the piezo-electric element expands and contracts.

Other embodiments disclosed herein include a piezo electric device, comprising: a piezo electric element wherein the piezo electric element changes its length when an electrical signal is applied to its terminals; a piezo holder adapted to accept the piezo electric element; and a piezo cover having a plurality of lateral openings adapted to allow signal wires to pass through and connect to the terminals of the piezo electric element, wherein the piezo holder is adapted to enable relative movement of the piezo holder and the piezo cover when the piezo electric element expands and contracts.

### BRIEF DESCRIPTION OF THE DRAWING

In the drawing:

FIG. 1 shows an isometric view of an illustrative piezo housing assembly, according to an embodiment;

FIG. 1A shows an exploded isometric view of the piezo housing assembly of FIG. 1, according to an embodiment;

FIG. 2 shows an isometric view of an illustrative piezo holder of the piezo housing assembly of FIG. 1A, according to an embodiment;

FIG. 3 shows an isometric view of the piezo element of FIG. 1A, according to an embodiment;

FIG. 4 shows an isometric view of a piezo cover of FIG. 1A, according to an embodiment;

FIG. 4A shows a transparent isometric view of the piezo cover of FIG. 1A, according to an embodiment;

FIG. 5 and FIG. 5A each shows a different schematic exploded view of an illustrative piezo housing assembly, according to an embodiment;

FIG. 6 shows an isometric view of an illustrative plug that is connectable to a piezo housing assembly, according to an embodiment;

FIG. 7 shows an isometric view of an illustrative plug that is connected to a piezo housing assembly, according to an embodiment;

FIG. 8 shows a schematic view of a push screw designed for securing the piezo housing assembly in place, according to an embodiment; and

FIG. 9 shows a schematic view of an elongated piezo housing assembly, according to an embodiment.

### DETAILED DESCRIPTION

It is important to note that the embodiments disclosed herein are only examples of the many advantageous uses of the innovative teachings herein. In general, statements made in the specification of the present application do not necessarily limit any of the various claimed embodiments. Moreover, some statements may apply to some inventive features but not to others. In general, unless otherwise indicated, singular elements may be in plural and vice versa with no loss of generality. In the drawings, like numerals refer to like parts through several views.

The disclosure provides a housing assembly for a piezo electric device that allows transferring the actuation movement of the piezo-electric device within the housing to the outside while enclosing and protecting the piezo-electric device itself. The housing assembly includes a piezo holder, a piezo cover featuring openings for signal wire passage, and the piezo holder and piezo cover may each have a mating surface for connecting the housing assembly to respective target surfaces to which the force of the piezo-electric material will be applied. The piezo holder's side walls enable relative movement with respect to the piezo cover to accommodate actuator expansion and contraction. Upon assembly, flexible materials may be used to seal the openings to protect the piezo-electric material from the external environment. In an embodiment, the connection between the piezo holder and the piezo cover is externally sealed, i.e., covered, by a flexible substance.

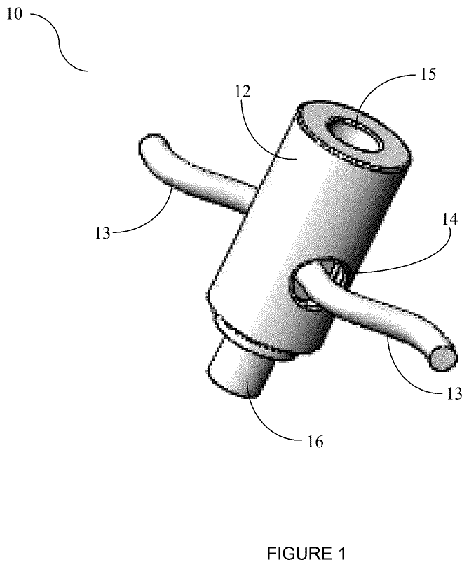

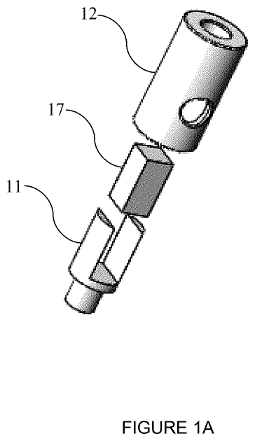

FIG. 1 shows an isometric view of an illustrative piezo housing assembly 10 according to an embodiment, while FIG. 1A shows an exploded isometric view of a piezo housing assembly 10. According to an embodiment, the housing of piezo housing assembly 10 includes a piezo holder 11 and a piezo cover 12. The piezo holder 11 is designed to receive, hold, and enable movement of a piezo-electric actuator, e.g., piezo-electric element 17 which is shown in position in piezo housing assembly 10 in FIG. 1A, as further discussed herein below. The piezo cover 12 includes openings, e.g., the openings 14. The openings 14 are designed to allow signal wires, e.g., signal wires 13 shown in FIG. 1, to pass through the piezo cover 12 and to the piezo-electric element 17 shown at least in FIGS. 1A, 5, and 7.

In an embodiment, the piezo housing assembly 10 includes a first mating surface 15 and a second mating surface 16. The first mating surface 15 is designed to attach (and detach) the piezo housing assembly 10 via the piezo cover 12 to a target surface, e.g., a pin in another component/system (not shown). According to another embodiment, the second mating surface 16, is designed to attach (and detach) the piezo housing assembly 10 via the piezo holder 11 to a target surface of something to which the piezo housing assembly 10 is coupled, e.g., a recess in another part to which the piezo housing assembly 10 is coupled, to a surface, i.e. bone to which the piezo housing assembly 10 is coupled, to a system to which the piezo housing assembly 10 is coupled, and the like.

For example, a target surface may be located at a surface of the cochlear wall. More specifically, with regard to hearing aids, as is well known, some advanced hearing aids incorporate piezo-electric actuators to generate sound vibrations. These actuators help in amplifying and transmitting sound to the inner ear, thus improving hearing for individuals with hearing impairments. With regard to prosthetics, as is well known, in some advanced prosthetic limbs and devices, piezo-electric actuators can be used to create more natural movements. Such piezo-electric actuators can provide precise control over joint movements, making the prosthetic limb more functional and responsive to the user's commands.

There are typically two target surfaces to which the piezo housing assembly 10 is attached, one at each end thereof. Where the target surfaces are depends on the application to which the piezo housing assembly 10 is being put. As such, when piezo housing assembly 10 is implanted in a body, e.g., in a human body, in some embodiments, the target surface may both be within the body. In some embodiments, attachment of the piezo housing assembly 10 to one or both of the target surfaces may be done during a surgical procedure, e.g., where the piezo housing is implanted.

In a further embodiment, the piezo housing assembly 10 may include a connecting means that is mounted to the piezo holder 11, such as a mating pin 16. The mating pin 16 may be used to attach and detach the piezo housing assembly 10 to and from a target surface (not shown). The connecting means may be of any length or shape, pointed, screw like, sharp or even be a recess shape to meet the required application. It should be noted that the connecting means may be different from the one described herein without departing from the scope of the disclosure.

Also, the piezo holder 11 shown in FIG. 1 has a cylindrical shape however, the piezo holder 11 may be implemented as rectangular or in any other shape as long as it matches the shape of the opening 41 in piezo cover 12 and allows relative movement of the piezo holder 11 and piezo cover 12 when the piezo-electric element 17 expands and contracts.

It should be noted that the piezo holder 11 may be constructed of any material that does not excessively absorb the translation of the piezo-electric element 17. Preferred materials are metals, metal alloys and ceramics. Advantageously, all or some of the surfaces of the piezo holder 11 may be coated with a protective coating such as Parylene C or layers of compounds like Alumina deposited by ALD or similar process or any other suitable protective coating.

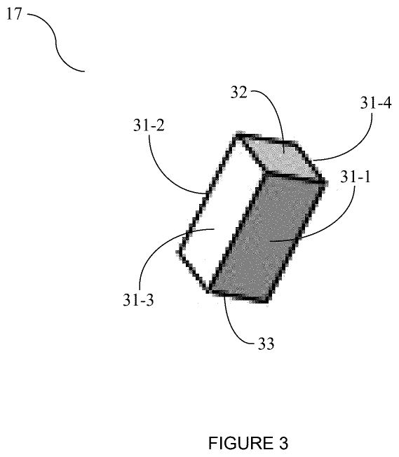

Reference is now made to FIG. 3 which shows the piezo-electric element 17 of FIG. 1A. In an embodiment, the piezo-electric element 17 has a top surface 32, bottom surface 33, a first lateral surface 31-1, a second lateral surface 31-2, a third lateral surface 31-3, and a fourth lateral surface 31-4. The piezo-electric element 17 consists of a piezo-electric material or stack of piezo-electric layers which changes its length when an electrical field is applied over its two terminals, e.g., the first lateral surface 31-1 and the second lateral surface 31-2.

For example, a piezo ceramic stack actuator, such as PI Ceramic PL022.3, is shown in FIG. 3. The top surface 32 and the bottom surface 33 move towards or away from each other when voltage is applied on electrical contacts that are located on the first lateral surface 31-1 and the second lateral surface 31-2 of the piezo-electric element 17. The bottom surface 33 is bonded to the piezo holder 11, of FIG. 1A, and the top surface 32, of FIG. 1A, is bonded to the piezo cover 12 so as to cause the piezo holder 11 to move towards the piezo cover 12 or away from the piezo cover 12. It should be noted that before assembly, one or more surfaces of the piezo-electric element 17 may be coated with a protective coating such as Parylene C or layers of compounds like Alumina deposited by ALD or similar process or any other suitable protective coating.

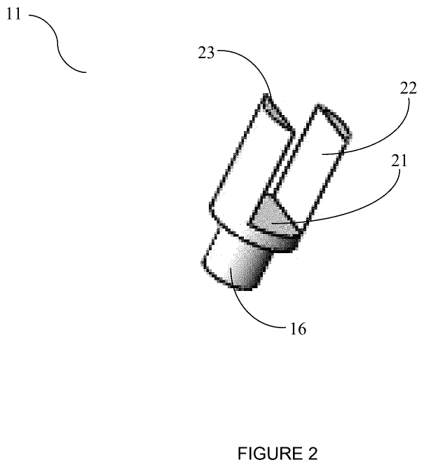

Reference is now made to FIG. 2. In an embodiment, the piezo holder 11 of FIG. 1A consists of a piezo mating surface 21 and two walls 22 that are partially surrounding the piezo mating surface 21. The piezo mating surface 21 is adapted to receive the bottom surface 33 of the piezo-electric element 17. The walls 22 are positioned in parallel to each other so that they partially cover two sides of the piezo-electric element 17 while defining a space for the piezo-electric element 17 to perform a relative movement of the piezo holder 11 and the piezo cover 12 when the piezo-electric element 17 expands or contracts. In other words, when the piezo-electric element 17 expands it pushes the piezo holder 11 and the piezo cover 12 axially away from each other while when the piezo-electric element 17 contracts it pulls the piezo holder 11 and the piezo cover 12 axially toward each other.

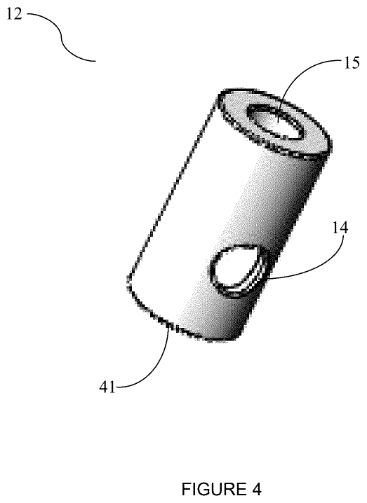

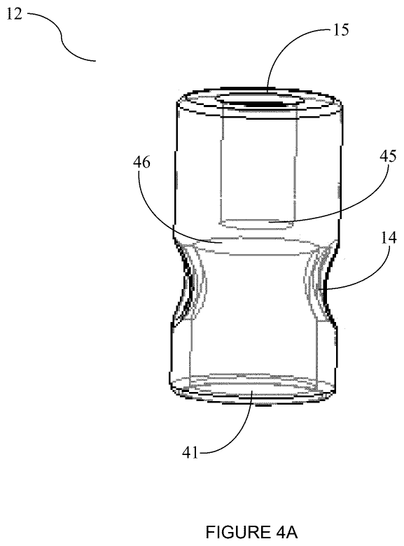

In an embodiment, an outer diameter of the piezo holder 11 is slightly smaller than an inner diameter of the bottom opening 41 (of FIG. 4) of the piezo cover 12, allowing the bottom opening 41 of the piezo cover 12 to receive the walls 22 of the piezo holder 11.

In an embodiment, the length of the walls 22 is equal. Each wall 22 has an identical top flat surface 23. In an embodiment, the length of the walls 22 is shorter than the length of the piezo-electric element 17. Thus, when the piezo housing assembly 10 is assembled, the bottom surface 33 (FIG. 3) of the piezo-electric element 17 meets the piezo mating surface 21 (FIG. 2), and the top surface 32 (FIG. 3) of the piezo-electric element 17 meets an inner and upper flat surface 46 (FIG. 4A) of the piezo cover 12.

Returning to FIG. 1, in an embodiment, after the piezo housing assembly 10 is assembled and the signal wires 13 are connected to the piezo-electric element 17, a flexible material, such as a silicone rubber, is poured into the openings 14 to seal the openings. In a further embodiment, a flexible material, such as silicone rubber, can be also applied around the opening 41 (FIG. 4A) of the piezo cover 12 to seal and attach both the piezo cover 12 and the piezo holder 11.

According to one embodiment, advantageously, the piezo housing assembly 10 is coated with protective coatings such as Parylene C or layers of compounds like Alumina deposited by ALD or similar process. According to a further embodiment, one of the signal wires 13 may be replaced by the metal of the piezo holder 11 or the piezo cover 12 that will be used as a signal conductor. In yet another embodiment, one of the wires 13 can be replaced by the metal of the piezo holder 11 and the other wire 13 by the metal of the piezo cover 12.

Reference is now made to FIG. 4 which shows the piezo cover 12. According to one embodiment, the piezo cover 12 consists of a hollow cylindrical body having an opening 41 at a first side of the piezo cover 12, at least two lateral openings 14 positioned on the hollow cylindrical body, and a first mating surface 15. The hollow cylindrical body of the piezo cover 12 is designed to accept therein the walls 22 (FIG. 2) of the piezo holder 11.

Reference is now made to FIG. 4A which shows a transparent view of the piezo cover 12. The inner and upper flat surface 46 is designed to meet the top surface 32 of the piezo-electric element 17. The lateral openings 14 allow the wires 13 (of FIG. 1) to connect through the hollow cylindrical body of the piezo cover 12 and pass electric signal to the piezo-electric element 17. According to one embodiment, during assembly, the wires 13 may be attached to terminals of the piezo-electric element 17 that are positioned at the first lateral surface 31-1 and the second lateral surface 31-2 of the piezo-electric element 17. According to another embodiment, the wires 13 may be attached to the terminals through the openings 14.

Also shown in FIG. 4A is the first mating surface 15. It should be noted that the first mating surface 15 shown in FIG. 4A is only one implementation of a connecting means which connects the piezo cover 12 of the piezo housing assembly 10 to a target surface (not shown), such target surfaces being described hereinabove. The first mating surface 15 may be implemented in any depth or shape, a protrusion, screw like, and the like, to meet the required application.

The piezo cover 12 of FIG. 4A is implemented as having cylindrical body. However, the piezo cover's body may be implemented as having rectangular body or in any other shape as long as it matches the shape of the piezo holder 11 and allows relative movement of the piezo holder 11 and piezo cover 12 when the piezo-electric element 17 expands or contracts.

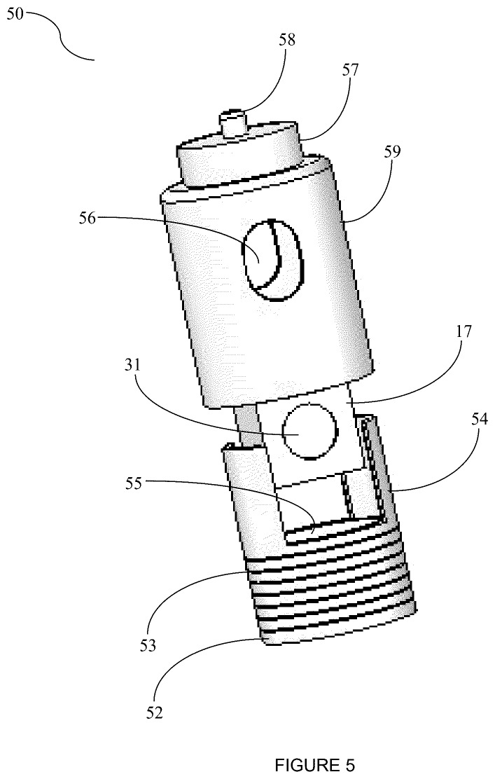

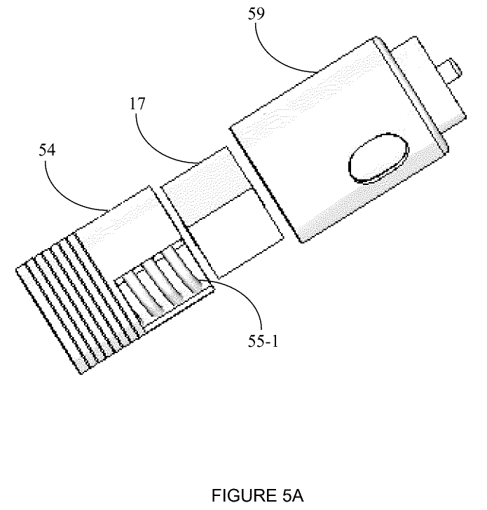

FIG. 5 and FIG. 5A each shows a different schematic exploded view of an illustrative piezo housing assembly 50, according to an embodiment. The piezo-electric element 17 is adhesively attached to a piezo cover 59. A member 57 protrudes from an upper end of the piezo cover 59. The member 57 has a diameter that is smaller than the diameter of the piezo cover 59. The member 57 is designed to adapt the size of the actuation surface of the piezo to the size of a target surface (not shown), such target surface being described hereinabove. Thus, through use of a properly sized member 57 piezos that are otherwise the same may be adapted to be used in different applications having target surfaces of different sizes.

According to one embodiment, a pin 58 may be mounted to the member 57 such that the pin 58 can be inserted into a hole (not shown) in a target surface (not shown). In this embodiment both the member 57 and the pin 58 are designed to adapt the size of the actuation surface of the piezo to the size of a target surface (not shown), such target surface being described hereinabove. Thus, through use of a properly sized member 57 and pin 58 piezos that are otherwise the same may be adapted to be used in different applications having target surfaces of different sizes. By inserting the pin 58 into the target surface the connection between the piezo and the target surface may be more robust so as to avoid unintentional movement, e.g., slippage, of the piezo housing assembly 10 during its operation.

According to an embodiment, signal wires, e.g., signal wires 13 of FIG. 1, that are electrically connected to the piezo-electric element 17 pass through openings 56 that allow for better access for either passing pre-soldered signal wires or for attaching signal wires to piezo-electric element 17. It should be noted that the openings 56 may be round, elliptical, etc., without departing from the scope of the invention.

In an embodiment, a piezo holder 52, which holds the piezo-electric element 17, fits axially into the piezo cover 59 while the lateral openings 56 are positioned next to the walls 54, but not covering the walls 54, allowing movement of the piezo holder 52 and the piezo cover 59 without interfering the signal wires that feed electric signals to the piezo-electric element 17 via the lateral opening 56.

In an embodiment, the piezo-electric element 17 may be adhesively attached to the piezo cover 59 or the piezo holder 52. The piezo holder 52 may have a recess 55 that is designed to contain a spring, e.g., the spring 55-1 which is shown only in FIG. 5A. The spring 55-1 is adapted to compensate for deformation of one or two of the target surfaces, while keeping the force produced by the piezo almost unchanged. According to another embodiment, the spring 55-1 is used for inserting the piezo assembly 50 into place easier as it allows to change the height of the piezo assembly 50. In an embodiment, the force exerted by the piezo housing assembly 50 may be determined based on the electrical parameters of the piezo-electric element 17, the electrical signal provided to the piezo-electric element 17 and the characteristics of the spring 55-1.

In an embodiment, the force exerted by the piezo housing assembly 50 may be determined based on the number of visible marks, e.g., visible ring marks 53, on the outside surface of piezo holder 52 that are still visible after piezo holder 52 is inserted into piezo cover 59. This is because the piezo cover 59 may hide some of the ring marks 53, depending on how much the spring was compressed when the piezo housing assembly 50 was inserted into its target position, i.e., coupled to the target surfaces, the expansion distance, i.e., length of the piezo-electric element 17, e.g., with respect to a resting baseline, and the parameters of the spring 55-1. Furthermore, how much the spring 55-1 is compressed may also be determined knowing the above factors.

It should be noted that the piezo holder 52 may be made in any shape or size, as required, to fit into the target location (not shown).

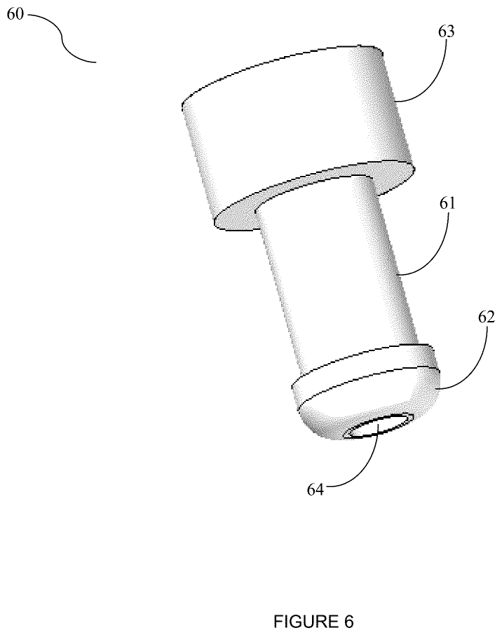

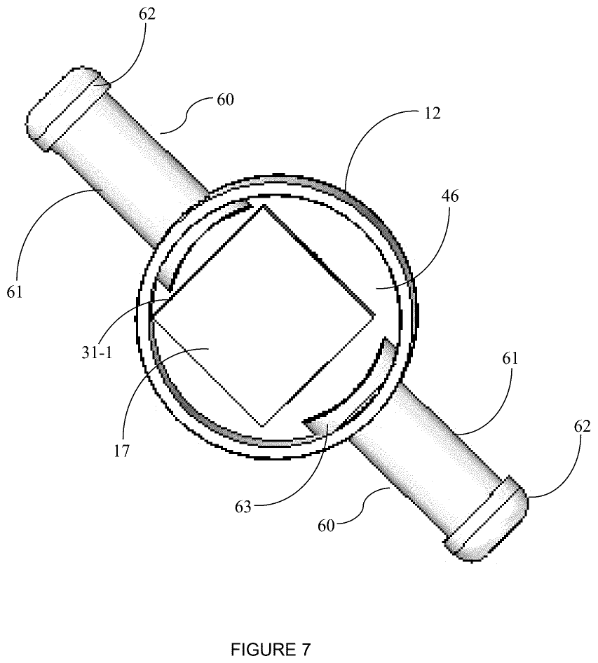

Reference is now made to FIG. 6 which shows a schematic drawing of a plug 60, according to an embodiment. The plug 60 may include a bottom end 63 having a first diameter, a shank 61 having a second diameter, an upper end 62 having a third diameter and a channel 64 therethrough. The plug 60 may be made of a flexible biocompatible polymer and may be inserted into, for example, the opening 14 (of FIG. 1). The first diameter is larger than the second diameter, the first diameter is larger than the third diameter and, the third diameter is larger than the second diameter. The upper end 62 and shank 61 are designed to be inserted through the opening 14 from the inside of piezo cover 12, with the upper end 62 entering opening 14 first and being followed by shank 61. The bottom end 63 of the plug 60 is typically larger than the opening 14 and so it passes up to the opening 14 and becomes lodged there, e.g. between the wall 31-1 of the piezo-electric element 17 (FIG. 3) and the inner diameter of the piezo cover 12 (FIG. 4A. This is shown in FIG. 7, which shows a transparent view of the establishment of a connection between the plug 60 and the piezo cover 12 of FIG. 4A. The channel 64 is a hollow shaft which extends from the bottom end 63 through the shank 61 and throughout the upper end 62. The channel 64 enables passing signal wires from the piezo-electric element 17 and outside to any device it may be, while sealing the inside of the piezo cover 12 (of FIG. 1) from the surrounding environment. It should be noted that the upper end 62, e.g. around any wires passing therethrough into channel 64, as well as the connection between the plug 60 and the inner diameter of the piezo cover 12, may be sealed by a flexible substance.

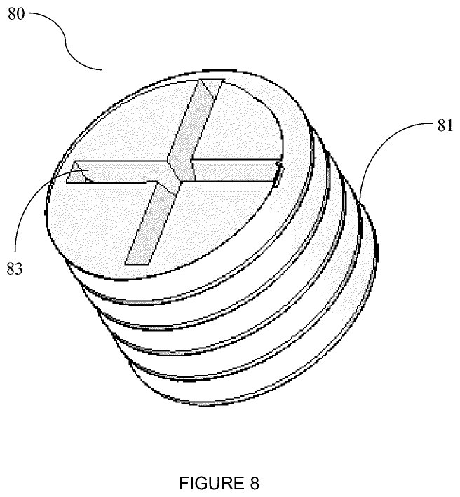

FIG. 8 shows a schematic view of an optional push screw 80 that may be used in embodiments where it is easier to drill a hole in one of the target surfaces rather than create a recess for it in place. The push screw 82 has threads 81 that are used for securing the push screw 82 inside the hole that was created within the target surface. In such an embodiment, a hole is drilled in place, i.e., in a target surface (not shown), and the piezo housing assembly 10 together with the signal wires 13, of FIG. 1, are inserted into the hole and pushed and held in place by, e.g., screwing the push screw 82 using a tool that fits into grooves 83. Then the push screw 82 may be used as the point of connection for the target surface to which one end of the piezo housing assembly ends, i.e., the piezo holder 84 or the piezo cover 86, is attached. For example, it may be necessary drill a hole in a human skull to implant a hearing aid device. After the hole in the skull is drilled, the push screw is screwed into the skull and the push screw is used as one of the target surfaces for the skull to which the housing assembly is attached.

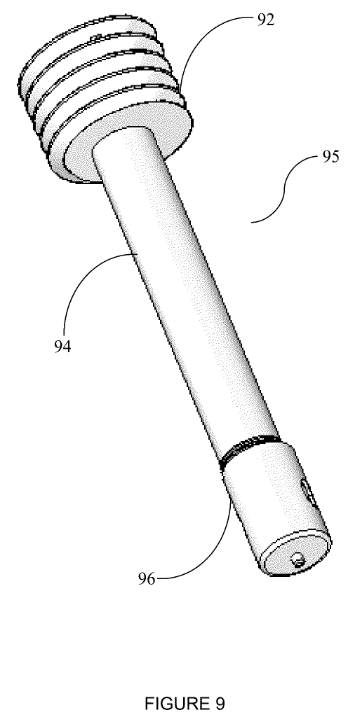

FIG. 9 shows a schematic view of an elongated piezo housing assembly housing assembly 95 that is attached to a push screw, e.g., the push screw of FIG. 8, according to an embodiment. It should be noted that the assembled components, i.e., elongated piezo housing assembly 95 that is attached to a push screw 92, illustrate the way the components would be attached to each other when assembled within a body, e.g., a human body. In an embodiment, the elongated piezo housing assembly 95 may include the same components as the piezo housing assembly 50 that is shown in FIG. 5, except that the elongated piezo housing assembly 95 has an elongated piezo holder 94 allowing the elongated piezo housing assembly 95 to connect directly, via the piezo holder 94, to a distant target surface, e.g., the push screw 92, as demonstrated in FIG. 9.

All examples and conditional language recited herein are intended for pedagogical purposes to aid the reader in understanding the principles of the disclosed embodiment and the concepts contributed by the inventor to further the art and are to be construed as being without limitation to such specifically recited examples and conditions. Moreover, all statements herein reciting principles, aspects, and embodiments of the disclosed embodiments, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

As used herein, the phrase “at least one of” followed by a listing of items means that any of the listed items can be utilized individually, or any combination of two or more of the listed items can be utilized. For example, if a system is described as including “at least one of A, B, and C,” the system can include A alone; B alone; C alone; 2A; 2B; 2C; 3A; A and B in combination; B and C in combination; A and C in combination; A, B, and C in combination; 2A and C in combination; A, 3B, and 2C in combination; and the like.

It should be understood that any reference to an element herein using a designation such as “first,” “second,” and so forth does not generally limit the quantity or order of those elements. Rather, these designations are generally used herein as a convenient method of distinguishing between two or more elements or instances of an element. Thus, a reference to first and second elements does not mean that only two elements may be employed there or that the first element must precede the second element in some manner. Also, unless stated otherwise, a set of elements comprises one or more elements.

What is claimed is:

1. A housing assembly for a piezo-electric element, comprising:
a piezo holder adapted to accept a piezo-electric element; and
a piezo cover having at least one lateral opening adapted to allow signal wires to pass through and connect to the piezo-electric element, wherein the piezo holder is adapted to enable relative movement of the piezo holder and the piezo cover when the piezo-electric element expands and contracts.

2. The piezo housing assembly of claim 1, wherein the piezo cover comprises a first mating surface adapted to attach the piezo housing assembly to a target surface.

3. The piezo housing assembly of claim 1, wherein the piezo holder comprises a mating surface adapted to attach the piezo housing assembly to a target surface.

4. The piezo housing assembly of claim 1, further comprising:
at least one connector mounted to at least one of the piezo holder and the piezo cover, the connector comprising a mating pin attached to attach and detach the piezo housing assembly to and from a target surface.

5. The piezo housing assembly of claim 1, wherein the piezo holder further comprises:
a piezo mating surface adapted to receive a bottom surface of the piezo-electric element; and,
a plurality of walls arranged in parallel to each other so as to partially surround the piezo mating surface, wherein the plurality of walls defines a space in which the piezo-electric element may perform a relative movement between the piezo holder and the piezo cover.

6. The piezo housing assembly of claim 1, wherein the piezo cover further comprises:
a hollow cylindrical body having a bottom opening at and at least one lateral opening positioned on the hollow cylindrical body; and
an inner and upper flat surface designed to meet a top surface of the piezo-electric element.

7. The piezo electric device of claim 1, wherein the piezo holder is further adapted to contain a spring therein.

8. The piezo housing assembly of claim 1 wherein at least one of the piezo holder and the piezo cover are coated with at least one of Parylene C and atomic layer deposition (ALD) coating.

9. The piezo housing assembly of claim 1, wherein the piezo-electric element changes its length when an electrical signal is applied to its terminals.

10. The piezo housing assembly of claim 1, further comprising:
at least one push screw adapted to be inserted into a hole drilled in a target surface.

11. The piezo housing assembly of claim 1, wherein the connection between the piezo holder and the piezo cover is externally sealed by a flexible substance.

12. A piezo-electric device, comprising:
a piezo-electric element wherein the piezo-electric element changes its length when an electrical signal is applied to its terminals;
a piezo holder adapted to accept the piezo-electric element; and
a piezo cover having at least one lateral opening adapted to allow signal wires to pass through and connect to the terminals of the piezo-electric element, wherein the piezo holder is adapted to enable relative movement of the piezo holder and the piezo cover when the piezo-electric element expands and contracts.

13. The piezo-electric device of claim 12, wherein the piezo-electric element is adhesively attached to at least one of the piezo cover and the piezo holder.

14. The piezo electric device of claim 12, wherein the piezo holder has a recess adapted to contain a spring.

15. The piezo electric device of claim 14, further comprising a spring inserted into the recess.

16. The piezo electric device of claim 12, wherein the piezo holder has visible marks on an outside surface of the piezo holder.

17. The piezo electric device of claim 16, wherein the visible marks on the outside surface of the piezo holder are ring-shaped.

18. The piezo electric device of claim 12, further comprising:
at least one plug inserted into one of the lateral openings, the at least one plug having a channel therethrough, and at least one of the signal wires passes through the channel.

19. The piezo electric device of claim 10, further comprising:
at least one push screw adapted to be inserted into a hole drilled in a target surface.

20. The piezo electric device of claim 12, wherein at least one of the piezo holder and the piezo cover are coated with at least one of Parylene C and atomic layer deposition (ALD) coating.

21. The piezo electric device of claim 12, wherein the connection between the piezo holder and the piezo cover is externally sealed by a flexible substance.
